(19) United States
(12) Patent Application Publication
(10) Pub. No.: US 2013/0157170 A1
(43) Pub. Date: Jun. 20, 2013

(54) METHOD FOR DEPOSITING CATALYST IN FUEL CELL, FUEL CELL MANUFACTURED BY THE SAME AND OPERATION APPARATUS FOR THE SAME

(71) Applicants: Joong Myeon BAE, Daeejon (KR); Sung Min Shin, Gyeongsangbuk-do (KR); Kun Ho Lee, Seoul (KR); Junhyun Kang, Seoul (KR)

(72) Inventors: Joong Myeon BAE, Daeejon (KR); Sung Min Shin, Gyeongsangbuk-do (KR); Kun Ho Lee, Seoul (KR); Junhyun Kang, Seoul (KR)

(21) Appl. No.: 13/442,616

(22) Filed: Apr. 9, 2012

(30) Foreign Application Priority Data
Dec. 15, 2011 (KR) 10-2011-0135655

(51) Int. Cl. H01M 8/10; C23C 16/06; C23C 16/44

(52) U.S. Cl. 429/483; 427/115; 118/715

(57) ABSTRACT

Provided are a method for depositing a catalyst in a fuel cell, a fuel cell obtained by the method, and an apparatus for operating the fuel cell. The method for depositing a catalyst in a fuel cell includes: oxidizing a catalyst provided at the top of the cathode with air introduced to the cathode under the operating condition of the fuel cell; and depositing the oxidized catalyst gas at the reactive zone of the cathode. The method allows deposition of an activated catalyst ingredient at the cathode of a fuel cell by disposing a catalyst (such as Pt, Ag, Pd, Ru, etc.) highly reactive to reduction of oxygen at the side to which oxygen is introduced, and oxidizing and vaporizing the catalyst under an actual operating condition.

### CROSS-REFERENCE TO RELATED APPLICATIONS

This application claims priority under 35 U.S.C. §119 to Korean Patent Application No. 10-2011-0135655, filed on Dec. 15, 2011, in the Korean Intellectual Property Office, the disclosure of which is incorporated herein by reference in its entirety.

### TECHNICAL FIELD

The following disclosure relates to a method for depositing a catalyst in a fuel cell, a fuel cell obtained by the method, and an apparatus for operating the fuel cell. More particularly, the following disclosure relates to a method for depositing a catalyst in a fuel cell, including disposing a catalyst (such as Pt, Ag, Pd, Ru, etc.) highly reactive to reduction of oxygen at the side to which oxygen is introduced, and oxidizing and vaporizing the catalyst under an actual operating condition to allow the activated catalyst ingredient to be deposited at a cathode, as well as a fuel cell obtained by the method and an apparatus for operating the fuel cell.

### BACKGROUND

In general, a fuel cell is a device by which chemical energy generated by oxidation of fuel is converted directly into electric energy. Such fuel cells are advantageous in that they have high efficiency, emit no carbon dioxide, are free from pollution, and generate no noise. In addition to those advantages, fuel cells have no limitation in fuel supply.

A fuel cell stack includes a unit cell having a cathode, electrolyte and an anode, a separator linking such unit cells with each other, and a seal linking a unit cell with a separator and linking such separators with each other.

Such fuel cells have been obtained by forming an electrode material, such as lanthanum strontium manganite (LSM, LaSrMnO₃) on an electrolyte substrate, such as yttria-stabilized zirconia (YSZ). However, there is still a need for developing novel technology in order to accomplish high cell efficiency.

### SUMMARY

An embodiment of the present disclosure is directed to providing a novel method for depositing a catalyst in a fuel cell and a method for operating a fuel cell to improve the efficiency of a fuel cell.

In one general aspect, there is provided a method for depositing a catalyst in a fuel cell having a cathode, electrolyte and an anode, the method including: oxidizing a catalyst provided at the top of the cathode with air introduced to the cathode under the operating condition of the fuel cell; and depositing the oxidized catalyst gas at the reactive zone of the cathode.

According to an embodiment, the cathode may have no oxygen conductivity, and then the reactive zone may be the three-phase boundary of the interface between the cathode and the electrolyte.

According to an embodiment, the oxidized catalyst gas may be deposited only at the three-phase boundary of the interface between the cathode and the electrolyte.

According to another embodiment, the cathode may have oxygen conductivity, and then the reactive zone may be the two-phase boundary of the cathode and oxygen.

According to still another embodiment, the deposition may be carried out by the difference in partial pressure between the catalyst and the three-phase boundary (TPB) or the two-phase boundary under the operating condition of the fuel cell.

According to yet another embodiment, the operating condition of the fuel cell may include temperature and oxygen partial pressure capable of oxidizing and vaporizing the catalyst, and the catalyst may be in the form of a mesh.

In another general aspect, there is provided a fuel cell having a cathode, electrolyte and an anode, wherein a catalyst oxidized by air introduced to the cathode is deposited at the interface between the cathode and the electrolyte.

According to an embodiment, the cathode may have no oxygen conductivity, and then the oxidized catalyst may be deposited at the three-phase boundary of the interface.

According to another embodiment, the cathode may have oxygen conductivity, and then the oxidized catalyst may be deposited at the two-phase boundary of the cathode and oxygen.

According to still another embodiment, the catalyst may be any one selected from the group consisting of Pt, Ag, Pd and Ru.

In still another general aspect, there is provided an apparatus for operating a fuel cell having a cathode, electrolyte and an anode, the apparatus including: an air supply line through which air is introduced to the cathode; and a catalyst provided in the air supply line, wherein the air oxidizes the catalyst before it is in contact with the cathode.

According to an embodiment, the catalyst may be any one selected from the group consisting of Pt, Ag, Pd and Ru, and the catalyst may be oxidized at the operating temperature of the apparatus.

As described hereinbefore, there is provided a method for depositing an activated catalyst ingredient at the cathode of a fuel cell, including disposing a catalyst (such as Pt, Ag, Pd, Ru, etc.) highly reactive to reduction of oxygen at the side to which oxygen is introduced, and oxidizing and vaporizing the catalyst under an actual operating condition. Therefore, it is possible to accomplish spontaneous catalyst deposition under the actual operating condition without any additional process for depositing a catalyst. In addition, it is possible to improve the quality of a fuel cell merely by disposing a catalyst that may be utilized in oxygen reduction in a solid oxide fuel cell at the inner part of a gas supply line.

### BRIEF DESCRIPTION OF THE DRAWINGS

The above and other aspects, features and advantages of the disclosed exemplary embodiments will be more apparent from the following detailed description taken in conjunction with the accompanying drawings in which:

FIG. 1 is a schematic view illustrating the basic mechanism of catalyst deposition according to the present disclosure;

FIG. 2 is a schematic view illustrating the method for depositing a catalyst according to an embodiment;

FIG. 3 is a graph illustrating the results of comparison of the quality of a fuel cell using a Pt mesh and Ag mesh as a catalyst according to FIG. 2 with that of a fuel cell using a conventional Co—Ni plated mesh having no activity toward reduction of oxygen;

FIG. 4 is a graph illustrating the improvement of the quality of a solid oxide fuel cell using, as a cathode, lanthanum strontium cobalt ferrite (LSCF) having oxygen ion conductivity, after catalyst deposition;

FIG. 5 and FIG. 6 are schematic views illustrating catalyst deposition zones depending on the oxygen ion conductivity of a cathode;

FIG. 7 is a scanning electron microscopy (SEM) photograph showing formation of particles at a three-phase boundary;

FIG. 8 is a SEM photograph of a sample subjected to energy dispersive spectrometry (EDS);

FIG. 9 shows the EDS analysis result of the heterogeneous material zone present at the red colored portion of FIG. 8;

FIG. 10 is a SEM photograph of a sample subjected to Pt detection through element mapping of transmission electron microscopy (TEM);

FIG. 11 is a photograph showing Pt detection of the sample through element mapping of TEM as shown in FIG. 10;

FIG. 12 is a schematic view illustrating a catalyst provided separately in an air inlet line while not using a current collector as a catalyst;

FIG. 13 is a graph illustrating the results of comparison of the catalyst used in the air inlet line as shown in FIG. 12 with the control; and

FIG. 14 is a schematic view showing the apparatus for operating a fuel cell according to an embodiment.

### DETAILED DESCRIPTION OF EMBODIMENTS

The advantages, features and aspects of the present disclosure will become apparent from the following description of the embodiments with reference to the accompanying drawings, which is set forth hereinafter. The present disclosure may, however, be embodied in different forms and should not be construed as limited to the embodiments set forth herein. Rather, these embodiments are provided so that this disclosure will be thorough and complete, and will fully convey the scope of the present disclosure to those skilled in the art. The terminology used herein is for the purpose of describing particular embodiments only and is not intended to be limiting of example embodiments. As used herein, the singular forms “a”, “an” and “the” are intended to include the plural forms as well, unless the context clearly indicates otherwise. It will be further understood that the terms “comprises” and/or “comprising”, when used in this specification, specify the presence of stated features, integers, steps, operations, elements, and/or components, but do not preclude the presence or addition of one or more other features, integers, steps, operations, elements, components, and/or groups thereof.

In one aspect, there is provided a method for depositing an activated catalyst ingredient at the cathode of a fuel cell, including disposing a catalyst (such as Pt, Ag, Pd, etc.) highly reactive to reduction of oxygen at the side to which oxygen is introduced, and oxidizing and vaporizing the catalyst under an actual operating condition. Therefore, it is possible to accomplish spontaneous catalyst deposition under the actual operating condition without any additional process for depositing a catalyst.

Materials that are present in the air supply path of a solid oxide fuel cell and are active toward reduction of oxygen may be deposited at the cathode due to the difference in oxygen partial pressure from the reactive zone (three-phase boundary or two-phase boundary) of the cathode. According to an embodiment, the catalyst is present in the air inlet path, and the catalyst may be a material different from a current collector or a current collector itself.

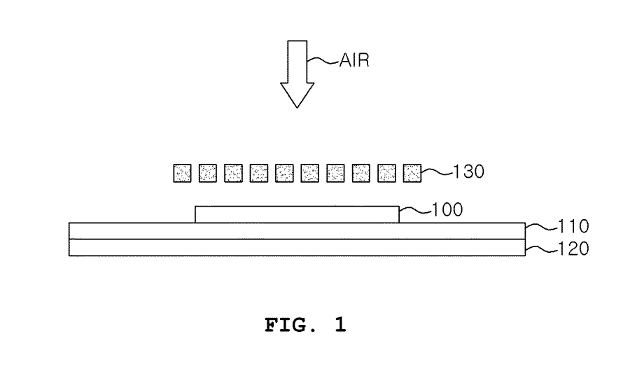

FIG. 1 is a schematic view illustrating the basic mechanism of catalyst deposition according to the present disclosure.

Referring to FIG. 1, a fuel cell including a cathode 100, electrolyte 110 and an anode 120 is shown. According to an embodiment, a catalyst 130 is provided at the flow path of air introduced to the cathode. The oxidized catalyst gas evaporated from the catalyst 130 is deposited due to the difference in oxygen partial pressure from the reactive zone of the cathode.

The zone where the catalyst oxidized by the air introduced to the cathode is deposited varies depending on oxygen conductivity of the cathode 100. In other words, when the cathode has oxygen conductivity, the catalyst is deposited at the cathode/oxygen two-phase boundary. However, when the cathode has no oxygen conductivity, the cathode is deposited at the cathode/electrolyte/oxygen three-phase boundary through the pores of the cathode as described hereinafter in detail.

According to an embodiment, the current collector, a mesh type metallic material (Pt) 130 is provided at the top of the cathode, LSM 100, and oxygen including air is blown into the cathode (LSM) under the operating condition of the fuel cell (600-1000° C., e.g. 800° C.). In the case of such an embodiment, the present inventors have found that the metallic material of the current collector present in the form of a mesh is oxidized and evaporated at the same time by the oxygen introduced to the cathode and the high-temperature condition, so that it is deposited at the cathode of the fuel cell as a catalyst. The present inventors also have found that such deposited catalyst improves the efficiency of the fuel cell. Therefore, in this manner, catalyst deposition is carried out simultaneously with the fuel cell operation, and thus there is no need for an additional chemical process for depositing a catalyst. According to an embodiment, Pt is used as the metal catalyst but other metals, such as Ag, Pd or Ru, having activity toward reduction of oxygen may be used as a catalyst.

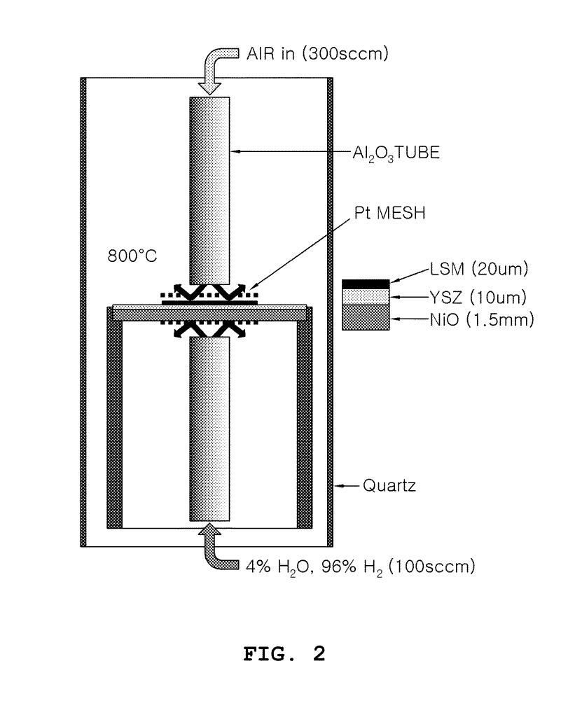

FIG. 2 is a schematic view illustrating the method for depositing a catalyst according to an embodiment.

Referring to FIG. 2, in this embodiment, a current collector itself serves as a catalyst while any catalyst material is not provided in the air inlet line. Therefore, as the current collector, a Pt mesh having activity toward reduction of oxygen is used. However, the scope of the present disclosure is not limited thereto. Rather, as shown in portion (b) of FIG. 12, a separate catalyst material may be provided in the air inlet line.

Referring again to FIG. 2, air introduced to the cathode is allowed to be in contact with the Pt collector mesh serving as a catalyst, and then is reduced at the cathode (LSM). Herein, the Pt ingredient evaporated by the air introduced to the cathode under a high-temperature condition is deposited in the fuel cell. When the cathode has no oxygen conductivity like LSM, the oxidized catalyst gas is transferred through the pores of the cathode and deposited at the interface between the cathode (LSM) and electrolyte, YSZ. Therefore, according to the method for depositing a catalyst disclosed herein, under the condition of temperature where a fuel cell is operated, a catalyst capable of being oxidized and vaporized at the same temperature is allowed to be in contact with air, so that Pt ingredient is deposited only at the LSM (cathode)/YSZ (electrolyte)/oxygen three-phase boundary (TPB) present at the interface between the cathode having no oxygen conductivity and the support. In this manner, it is possible to improve the efficiency of a fuel cell with no need for an additional oxidation and deposition process. It is thought that the deposition of Pt is derived from the difference in oxygen partial pressure generated between the TPB and Pt catalyst in such a manner that Pt present as a current collector at the top of the cathode (LSM) is oxidized and evaporated, and then is infiltrated to and deposited at the TPB. As a result, it is possible to improve the quality of a fuel cell.

However, when the cathode includes an oxygen conductive material, such as lanthanum strontium chromite (LSC) or lanthanum strontium ferrite (LSF), the catalyst gas may be deposited at the cathode/oxygen two-phase boundary. In this case, the catalyst deposition is carried out by the difference in oxygen partial pressure generated between the catalyst and the two-phase boundary.

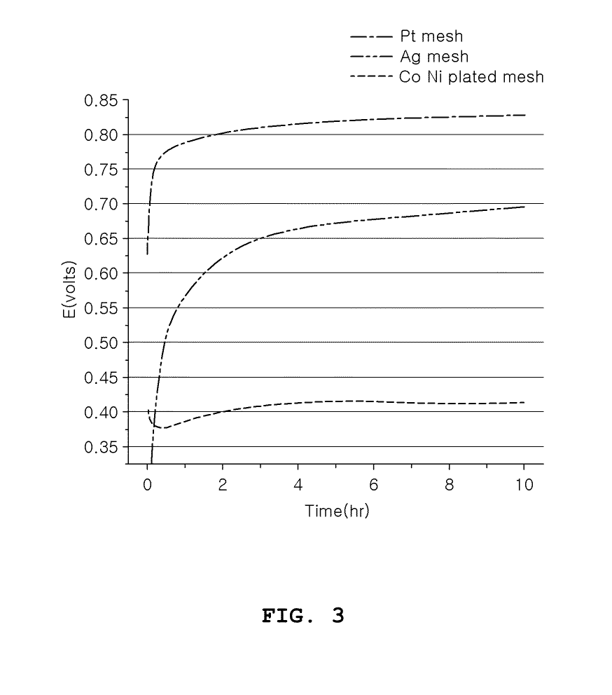

FIG. 3 is a graph illustrating the results of comparison of the quality of a fuel cell using a Pt mesh and Ag mesh as a catalyst according to FIG. 2 with that of a fuel cell using a conventional Co—Ni plated mesh having no activity toward reduction of oxygen.

Referring to FIG. 3, the voltage of the cell using LSM as a cathode is determined while the fuel cells are operated for 10 hours under the same current density of 0.5 A/cm². After the determination, the Co—Ni plated mesh shows little change in quality. However, it can be seen that when using the Pt and Ag collector, the cell shows a continuous increase in quality with time.

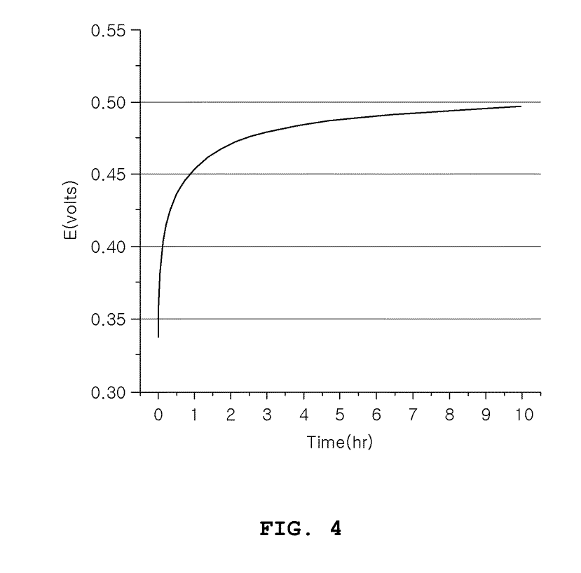

FIG. 4 is a graph illustrating the improvement of the quality of a solid oxide fuel cell using, as a cathode, lanthanum strontium cobalt ferrite (LSCF) having oxygen ion conductivity, after catalyst deposition.

Referring to FIG. 4, like the test results of FIG. 3 using LSM under the same operating condition (10 hours, current density 0.5 A/cm²), it can be seen that the cell shows a gradual increase in quality with time.

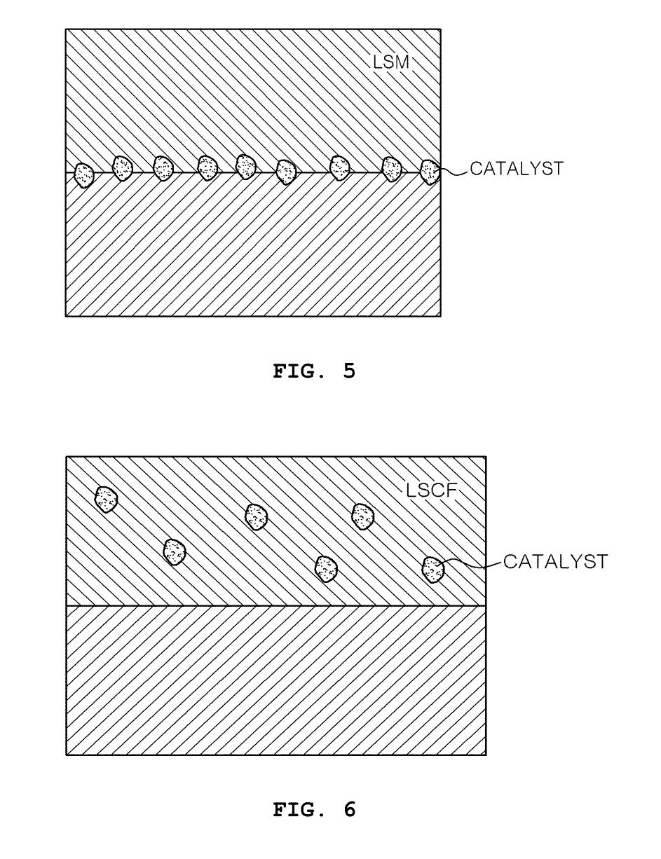

FIG. 5 and FIG. 6 are schematic views illustrating catalyst deposition zones depending on the oxygen ion conductivity of a cathode.

Referring to FIG. 5, when the cathode has no oxygen conductivity (e.g. LSM), the catalyst is deposited at the interface between the cathode and electrolyte due to the difference in oxygen partial pressure between the three-phase boundary present at the interface and the catalyst.

Referring to FIG. 6, when using a cathode (e.g. LSCF) having oxygen ion conductivity, the catalyst oxide gas oxidized and evaporated under the operating condition of a fuel cell is deposited at the two-phase boundary of the oxygen ion conductive cathode and oxygen. In other words, in this case, the oxidized and evaporated catalyst oxide gas may be deposited at the cathode itself as well as the interface with electrolyte. Thus, according to an embodiment of the present disclosure, the oxidized and evaporated catalyst is deposited at the reactive zone of the fuel cell, and the reactive zone varies with the oxygen ion conductivity of cathode.

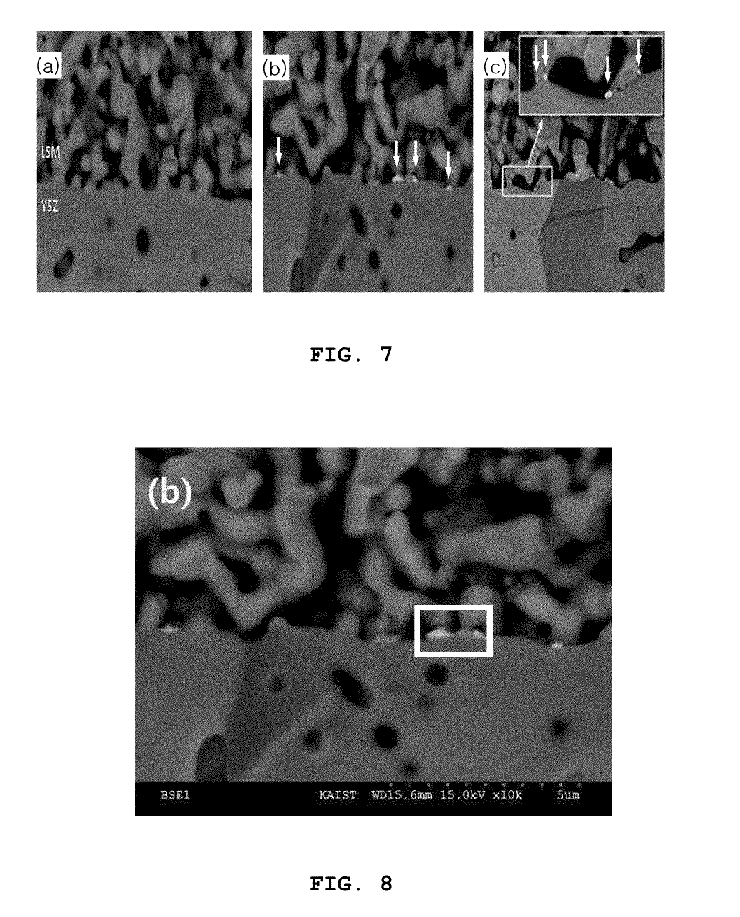

FIG. 7 is a scanning electron microscopy (SEM) photograph showing formation of particles at a three-phase boundary.

In FIG. 7, Portion (a) is a SEM photograph showing a fuel cell using a Co—Ni plated mesh, and Portion (b) and Portion (c) are photographs showing fuel cells using a Ag mesh and Pt mesh, respectively.

Referring to FIG. 7, after operating the fuel cell using each type of mesh, the backscattered electrons (BSE)-mode SEM image of the front sectional surface is observed. After the observation, it can be seen that when using the Ag mesh and Pt mesh, a heterogeneous material is formed at the three-phase boundary (see, the red arrow mark).

Energy dispersive spectrometry (EDS) analysis is carried out to analyze the composition of the heterogeneous material.

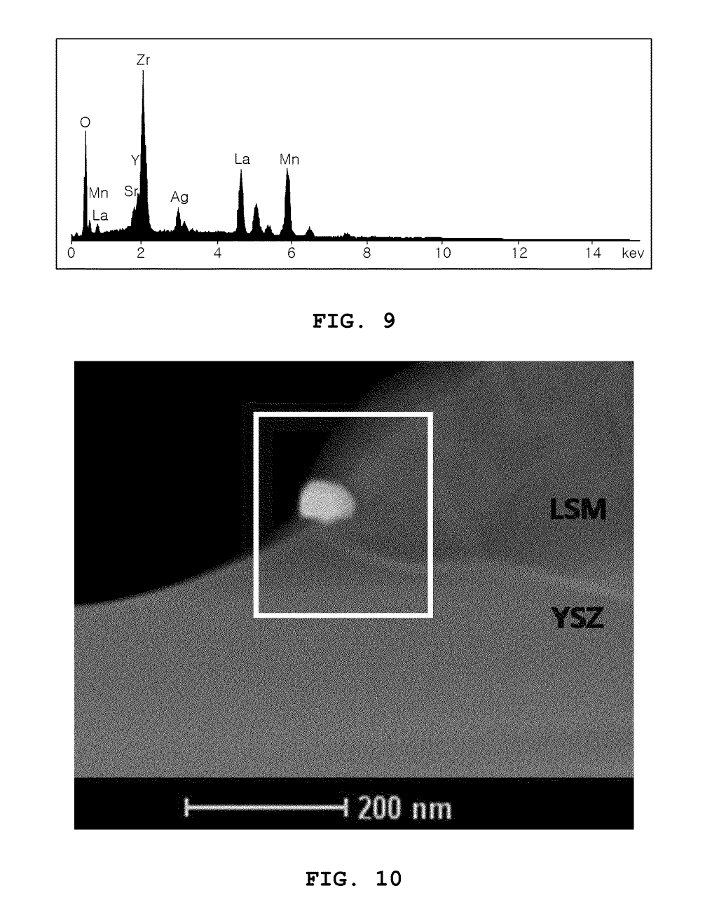

FIG. 8 is a SEM photograph of a sample subjected to EDS, and FIG. 9 shows the EDS analysis result of the heterogeneous material zone present at the red colored portion of FIG. 8.

It can be seen from FIG. 8 and FIG. 7 that the detected heterogeneous material is Ag. However, in the case of Pt, energy peaks are overlapped with those of Zr in EDS analysis, and thus it is difficult to identify the detection of Pt by way of such EDS analysis. Therefore, Pt detection is identified through an elementary mapping method through transmission electron microscopy (TEM).

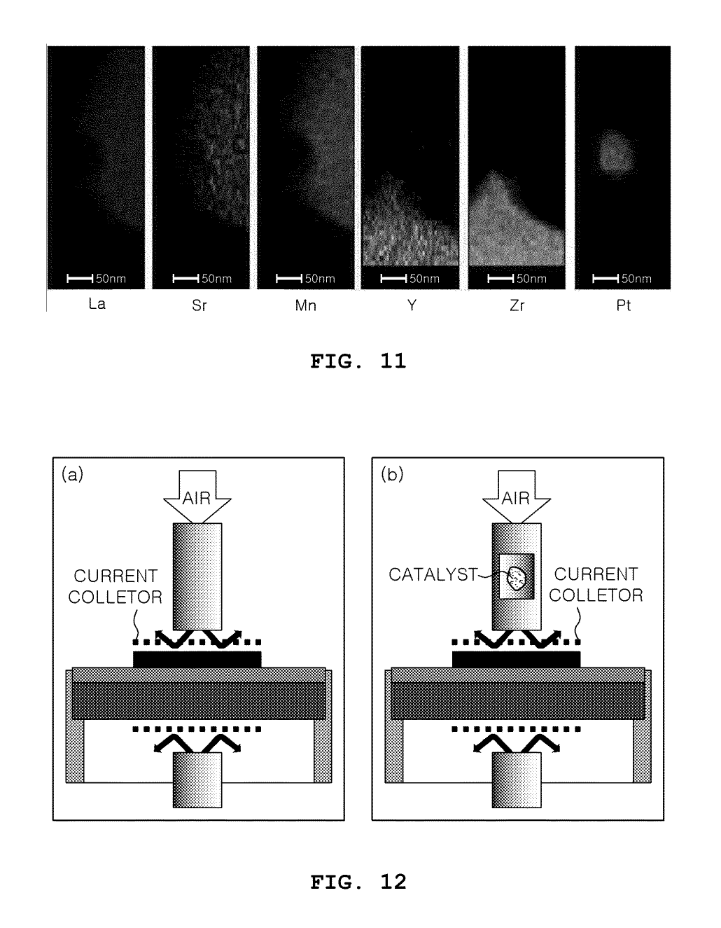

FIG. 10 is a SEM photograph of a sample subjected to Pt detection through element mapping of TEM, and FIG. 11 is a photograph showing Pt detection of the sample through element mapping of TEM as shown in FIG. 10.

Referring to FIG. 10 and FIG. 11, Pt is detected only at the microstructured zone where the heterogeneous material is formed. Therefore, it can be seen that the heterogeneous material detected from FIG. 10 is Pt.

FIG. 12 is a schematic view illustrating a catalyst provided separately in an air inlet line while not using a current collector as a catalyst. In FIG. 12, the current collector is a Co—Ni plated mesh having no activity toward reduction of oxygen.

Referring to Portion (b) of FIG. 12, a catalyst material is provided in the air inlet line through which air is introduced to the cathode, and the catalyst material is oxidized and evaporated by the air and deposited at the cathode.

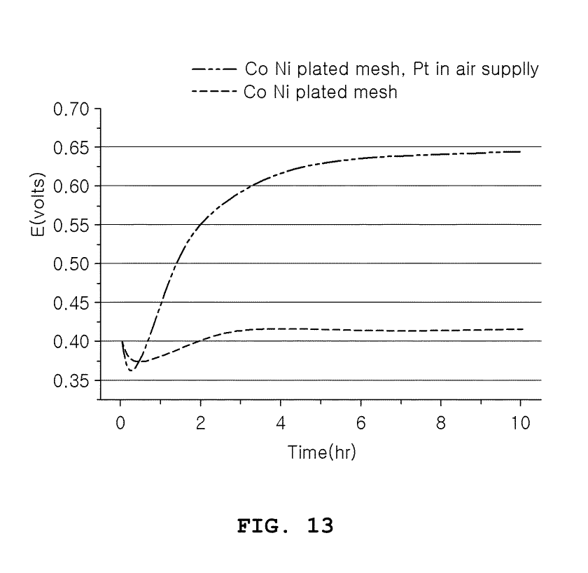

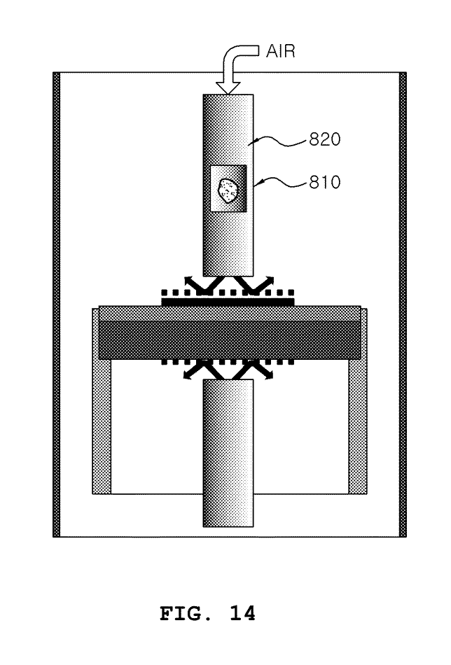

FIG. 13 is a graph illustrating the results of comparison of the catalyst used in the air inlet line as shown in FIG. 12 with the control.

Referring to FIG. 13, it can be seen that when disposing Pt in the air inlet line, the fuel cell shows a continuous improvement in its quality with time, as compared to the control.

FIG. 14 is a schematic view showing the apparatus for operating a fuel cell according to an embodiment.

Referring to FIG. 14, a catalyst 810 that may be utilized in oxygen reduction is disposed in an air supply line 820, and the air introduced to the air supply line is allowed to be in contact with the catalyst before it is in contact with the cathode of the fuel cell, so that the catalyst is oxidized. Particularly, according to an embodiment of the present disclosure, the contact between air and catalyst is carried out at a temperature of 600-1000° C. In this manner, the oxidized and evaporated catalyst oxide gas is deposited at the three-phase boundary of the interface with electrolyte due to the difference in oxygen partial pressure as described hereinbefore.

As can be seen from the foregoing, according to an embodiment of the present disclosure, it is possible to improve the quality of a fuel cell merely by disposing a catalyst in an air supply line, while avoiding a need for an additional deposition and oxidation process. In other words, catalyst deposition occurs spontaneously under an actual cell operating condition, thereby realizing high cost efficiency. Although Pt is used as a catalyst according to an embodiment, Ag, Pd, Ru, or the like may also be used as a catalyst, and the scope of the present disclosure is not limited thereto.

While the present disclosure has been described with respect to the specific embodiments, it will be apparent to those skilled in the art that various changes and modifications may be made without departing from the spirit and scope of the disclosure as defined in the following claims.

What is claimed is:

1. A method for depositing a catalyst in a fuel cell having a cathode, electrolyte and an anode, the method comprising:
oxidizing a catalyst provided at the top of the cathode with air introduced to the cathode under an operating condition of the fuel cell; and
depositing the oxidized catalyst gas at a reactive zone of the cathode.

2. The method according to claim 1, wherein the cathode has no oxygen conductivity, and then the reactive zone is three-phase boundary of an interface between the cathode and the electrolyte.

3. The method according to claim 2, wherein the oxidized catalyst gas is deposited only at the three-phase boundary of the interface between the cathode and the electrolyte.

4. The method according to claim 1, wherein the cathode has oxygen conductivity, and then the reactive zone is two-phase boundary of the cathode and oxygen.

5. The method according to claim 2, wherein said depositing is carried out by difference in partial pressure between the catalyst and the three-phase boundary under the operating condition of the fuel cell.

6. The method according to claim 4, wherein said depositing is carried out by difference in partial pressure between the catalyst and the two-phase boundary under the operating condition of the fuel cell.

7. The method according to claim 1, wherein the operating condition of the fuel cell includes temperature and oxygen partial pressure capable of oxidizing and vaporizing the catalyst.

8. The method according to claim 1, wherein the catalyst is in the form of a mesh.

9. A fuel cell having a cathode, electrolyte and an anode, wherein a catalyst oxidized by air introduced to the cathode is deposited at an interface between the cathode and the electrolyte.

10. The fuel cell according to claim 9, wherein the cathode has no oxygen conductivity, and then the oxidized catalyst is deposited at three-phase boundary of the interface.

11. The fuel cell according to claim 9, wherein the cathode has oxygen conductivity, and then the oxidized catalyst is deposited at two-phase boundary of the cathode and oxygen.

12. The fuel cell according to claim 9, wherein the catalyst is any one selected from the group consisting of Pt, Ag, Pd and Ru.

13. An apparatus for operating a fuel cell having a cathode, electrolyte and an anode, the apparatus comprising:
an air supply line through which air is introduced to the cathode; and
a catalyst provided in the air supply line,
wherein the air oxidizes the catalyst before it is in contact with the cathode.

14. The apparatus according to claim 13, wherein the catalyst is any one selected from the group consisting of Pt, Ag, Pd and Ru.

15. The apparatus according to claim 13, wherein the catalyst is oxidized at an operating temperature of the apparatus.
